(19) United States
(12) Patent Application Publication
(10) Pub. No.: US 2026/0060100 A1
(43) Pub. Date: Feb. 26, 2026

(54) SEMICONDUCTOR DEVICE AND VEHICLE

(71) Applicant: Rohm Co., Ltd., Kyoto-shi (JP)

(72) Inventors: Yoshimasa FUJISADA, Kyoto-shi (JP); Hajime USHIO, Kyoto-shi (JP)

(21) Appl. No.: 19/355,724

(22) Filed: Oct. 10, 2025

Related U.S. Application Data
(63) Continuation of application No. PCT/JP2024/013622, filed on Apr. 2, 2024.

(30) Foreign Application Priority Data
Apr. 18, 2023 (JP) 2023-067669

(51) Int. Cl. H01L 23/00; H01L 23/31; H01L 23/495

(52) U.S. Cl. CPC H01L 24/37; H01L 23/3114; H01L 23/49562; H01L 24/32; H01L 24/40; H01L 24/48; H01L 24/73; H01L 2224/32245; H01L 2224/37013; H01L 2224/37147; H01L 2224/40175; H01L 2224/48175; H01L 2224/73221; H01L 2224/73263; H01L 2224/73265; H01L 2924/13091; H01L 2924/35121

(57) ABSTRACT

A semiconductor device includes: a first lead including a base portion; a semiconductor element mounted on a first side of the base portion in the thickness direction and including a first electrode; a second lead spaced apart from the base portion in a first direction perpendicular to the thickness direction; a first conductive member electrically bonded to the first electrode and the second lead; and a sealing resin. The first conductive member includes a first portion bonded to the first electrode via a conductive first bonding layer. The first portion includes a first surface and a second surface respectively facing the first side and a second side in the thickness direction. The first portion includes a plurality of first recesses that are recessed from the first surface and a plurality of second recesses that are recessed from the second surface.

### TECHNICAL FIELD

The present disclosure relates to a semiconductor device and a vehicle provided with the semiconductor device.

### BACKGROUND ART

Semiconductor devices provided with semiconductor elements are proposed in various configurations. WO2022/014387 discloses an example of a conventional semiconductor device. The semiconductor device disclosed in the document is provided with a plurality of leads, a semiconductor element, a plurality of conductive members, and a sealing resin. The conductive members include a metal clip and a wire. The metal clip is bonded to an electrode disposed on the upper surface of the semiconductor element and to a lead. The wire is bonded to an electrode disposed on the upper surface of the semiconductor element and to another lead. The sealing resin covers the semiconductor element and the conductive members. The metal clip is bonded and electrically connected to the electrode on the semiconductor element via a bonding layer. In such a semiconductor device, heat generated by the semiconductor element causes thermal expansion and contraction of various parts. The sealing resin has a greater linear expansion coefficient than either the metal clip or the semiconductor element. Due to the difference in their linear expansion coefficients, the sealing resin undergoes thermal contraction, which can generate significant stress near the perimeter of the semiconductor element. This can cause defects such as peeling of the sealing resin from the metal clip, or bonding failure between the metal clip and the bonding layer on the semiconductor element.

### BRIEF DESCRIPTION OF THE DRAWINGS

FIG. 1 is a perspective view of a semiconductor device according to a first embodiment of the present disclosure.

FIG. 2 is a plan view of the semiconductor device according to the first embodiment of the present disclosure.

FIG. 3 is a plan view of a portion of the semiconductor device according to the first embodiment of the present disclosure.

FIG. 4 is a bottom view of the semiconductor device according to the first embodiment of the present disclosure.

FIG. 5 is a side view of the semiconductor device according to the first embodiment of the present disclosure.

FIG. 6 is a front view of the semiconductor device according to the first embodiment of the present disclosure.

FIG. 7 is a sectional view taken along line VII-VII in FIG. 3.

FIG. 8 is a sectional view taken along line VIII-VIII in FIG. 3.

FIG. 9 is a sectional view taken along line IX-IX in FIG. 3.

FIG. 10 is a sectional view taken along line X-X in FIG. 3.

FIG. 11 is an enlarged view of a portion of FIG. 8.

FIG. 12 is an enlarged view of a portion of FIG. 9.

FIG. 13 is an enlarged view of a portion of FIG. 10.

FIG. 14 is a schematic diagram of a vehicle provided with the semiconductor device according to the first embodiment of the present disclosure.

FIG. 15 is a plan view of a portion of a semiconductor device according to a first variation of the first embodiment.

FIG. 16 is an enlarged sectional view of a portion of the semiconductor device according to the first variation of the first embodiment, with the section corresponding to that shown in FIG. 11.

FIG. 17 is a plan view of a portion of a semiconductor device according to a second variation of the first embodiment.

FIG. 18 is an enlarged sectional view of a portion of the semiconductor device according to the second variation of the first embodiment, with the section corresponding to that shown in FIG. 11.

FIG. 19 is a plan view of a portion of a semiconductor device according to a third variation of the first embodiment.

FIG. 20 is an enlarged sectional view of a portion of a semiconductor device according to a fourth variation of the first embodiment, with the section corresponding to that shown in FIG. 11.

FIG. 21 is a plan view of a portion of a semiconductor device according to a second embodiment of the present disclosure.

FIG. 22 is an enlarged sectional view of a portion of the semiconductor device according to the second embodiment, with the section corresponding to that shown in FIG. 11.

FIG. 23 is a plan view of a portion of a semiconductor device according to a third embodiment of the present disclosure.

FIG. 24 is a sectional view taken along line XXIV-XXIV in FIG. 23.

FIG. 25 is a sectional view taken along line XXV-XXV in FIG. 23.

### DETAILED DESCRIPTION OF EMBODIMENTS

The following describes preferred embodiments of the present disclosure in detail with reference to the drawings.

In the present disclosure, the terms such as “first”, “second”, “third”, and so on are used only as labels and not to imply an order of the items referred to by the terms.

In the present disclosure, the expressions “an object A is formed in an object B” and “an object A is formed on an object B” imply the situation where, unless otherwise specifically noted, “the object A is formed directly in or on the object B” and “the object A is formed in or on the object B, with something else interposed between the object A and the object B.” Likewise, the expressions “an object A is arranged in an object B” and “an object A is arranged on an object B” imply the situation where, unless otherwise specifically noted, “the object A is arranged directly in or on the object B” and “the object A is arranged in or on the object B, with something else interposed between the object A and the object B.” Further, the expression “an object A is positioned on an object B” implies the situation where, unless otherwise specifically noted, “the object A is positioned on the object B, in contact with the object B” and “the object A is positioned on the object B, with something else interposed between the object A and the object B.” The expression “an object A overlaps with an object B as viewed in a certain direction” implies the situation where, unless otherwise specifically noted, “the object A overlaps with the entirety of the object B” and “the object A overlaps with a portion of the object B.” In the present disclosure, the expression “a surface A faces in a direction B (or a first side or a second side in the direction B) is not limited, unless otherwise specifically noted, to the situation where the surface A forms an angle of 90° with the direction B but includes the situation where the surface A is inclined relative to the direction B.

### First Embodiment

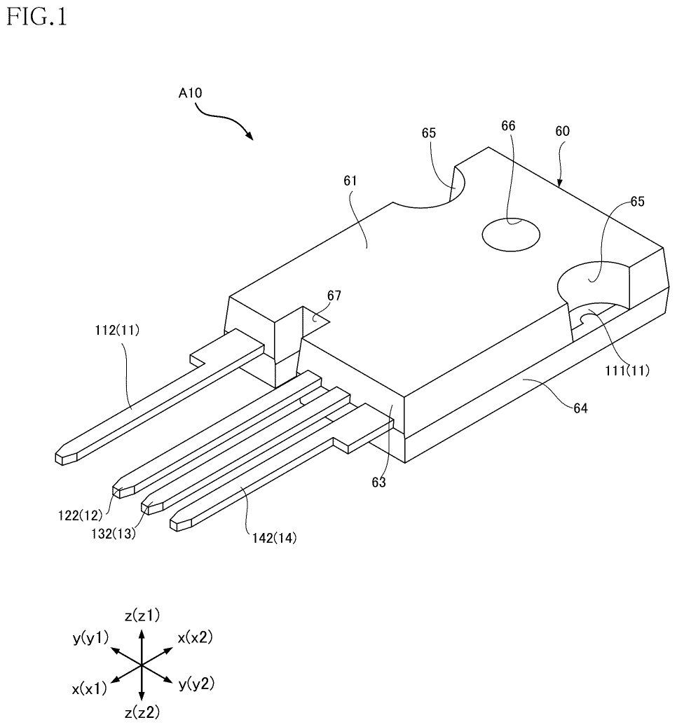

FIGS. 1 to 13 show a semiconductor device according to a first embodiment of the present disclosure. The applications of the semiconductor device A10 of the present embodiment are not particularly limited and include use in electronic devices having a power conversion circuit, such as DC-DC converters. The semiconductor device A10 includes a first lead 11, a second lead 12, a third lead 13, a fourth lead 14, a semiconductor element 20, a first conductive member 30, a second conductive member 40, a third conductive member 50, and a sealing resin 60.

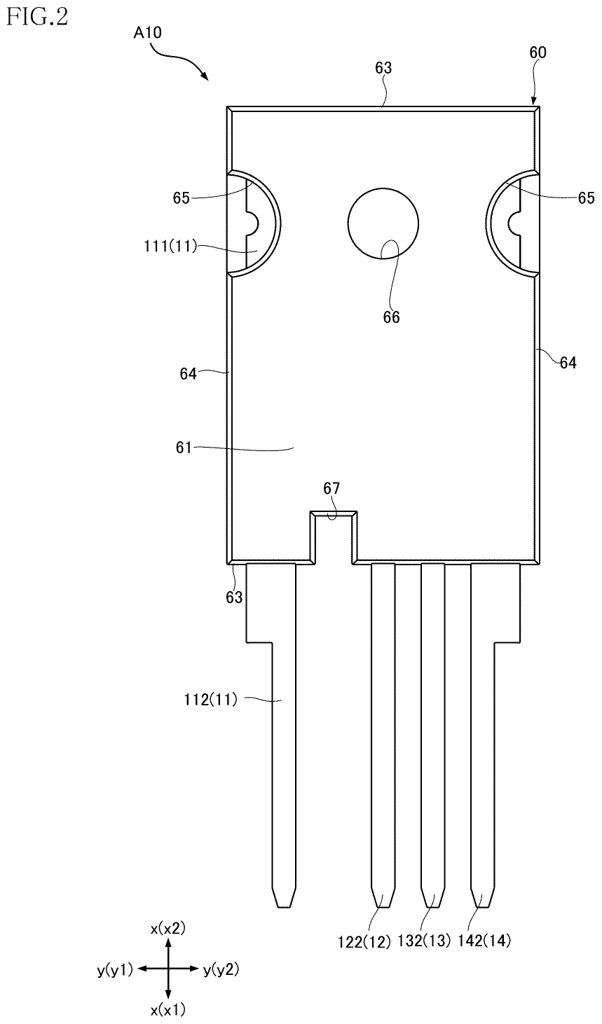

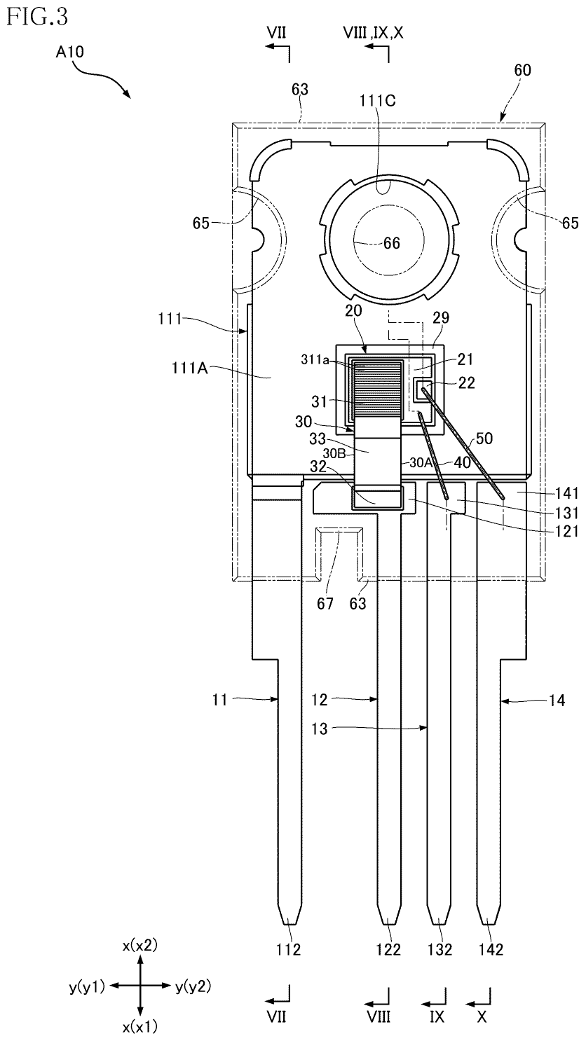

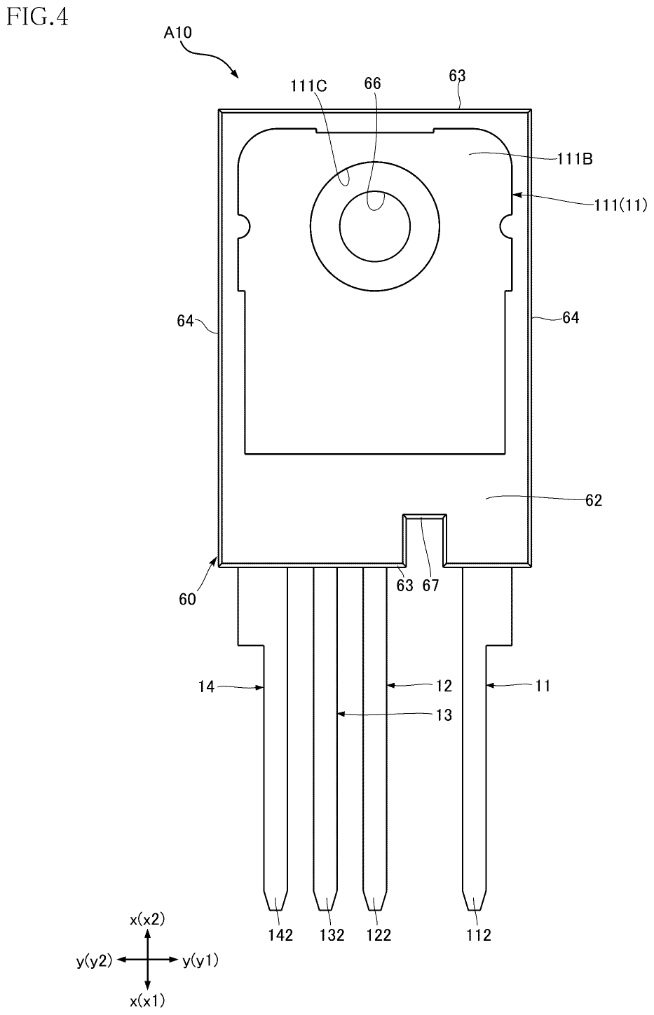

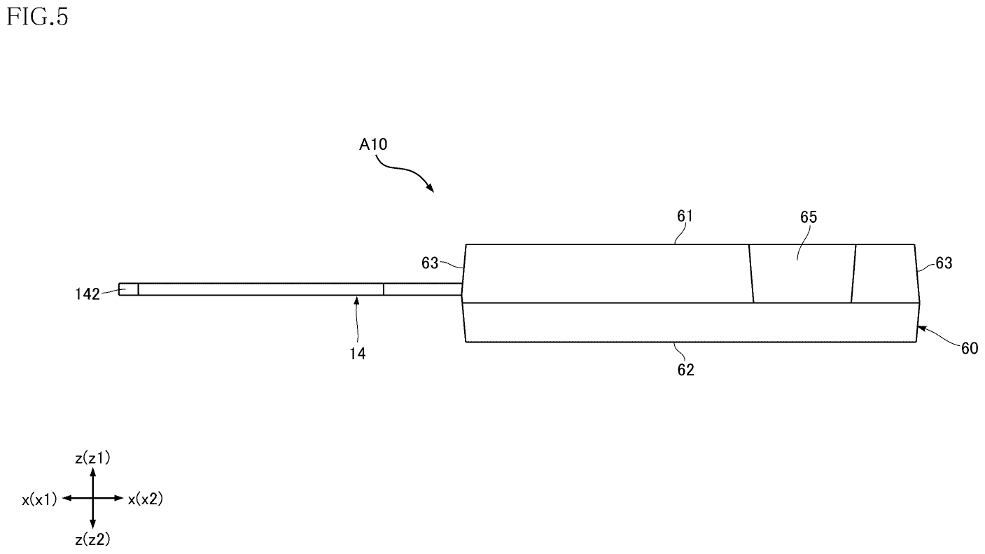

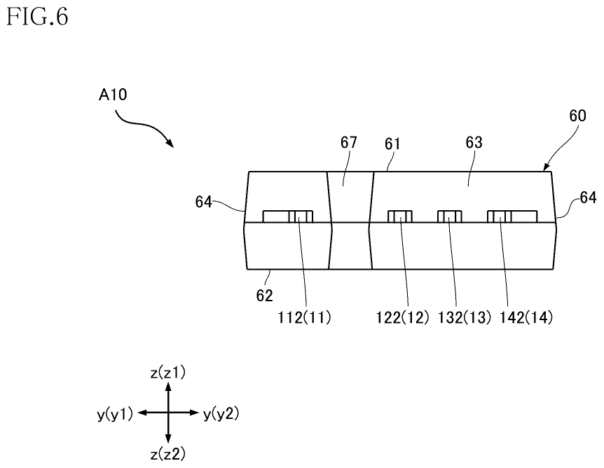

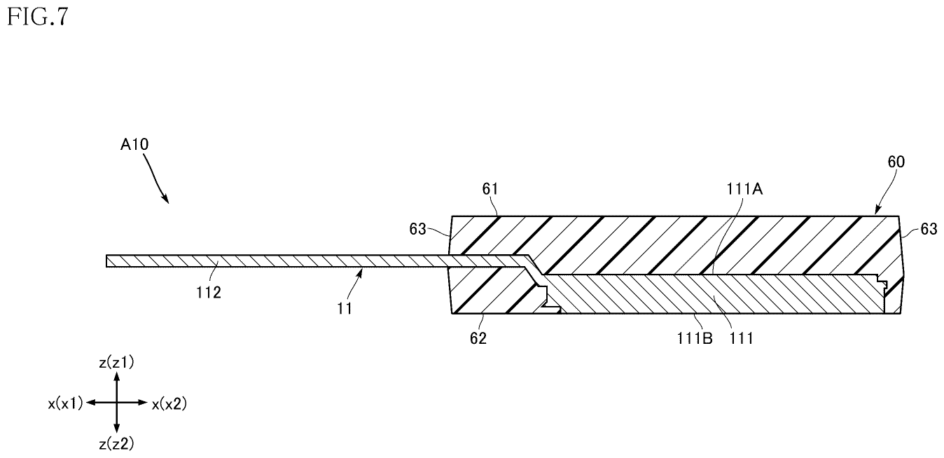

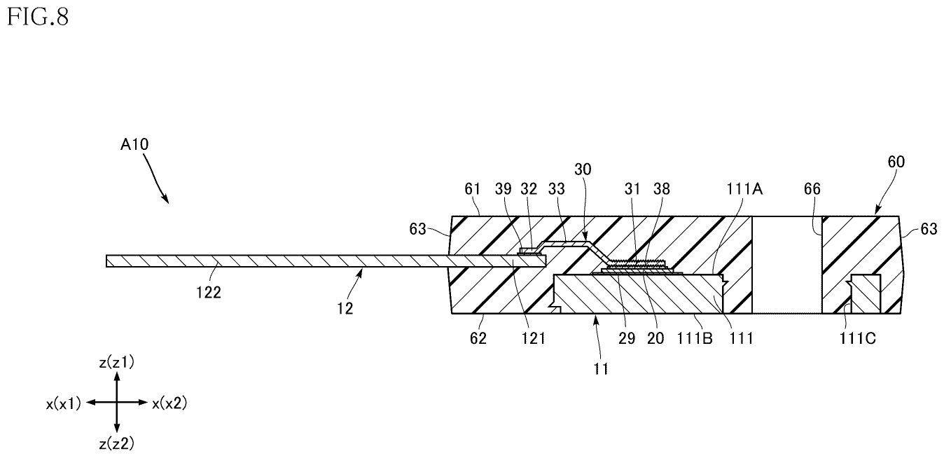

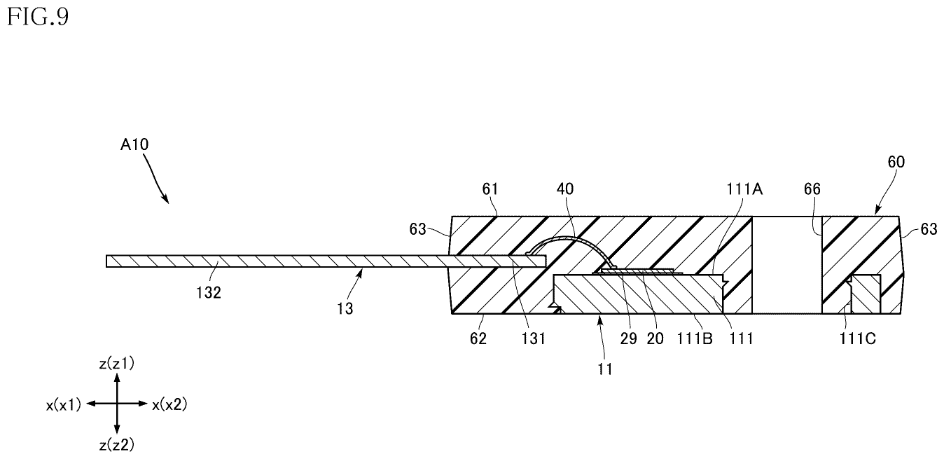

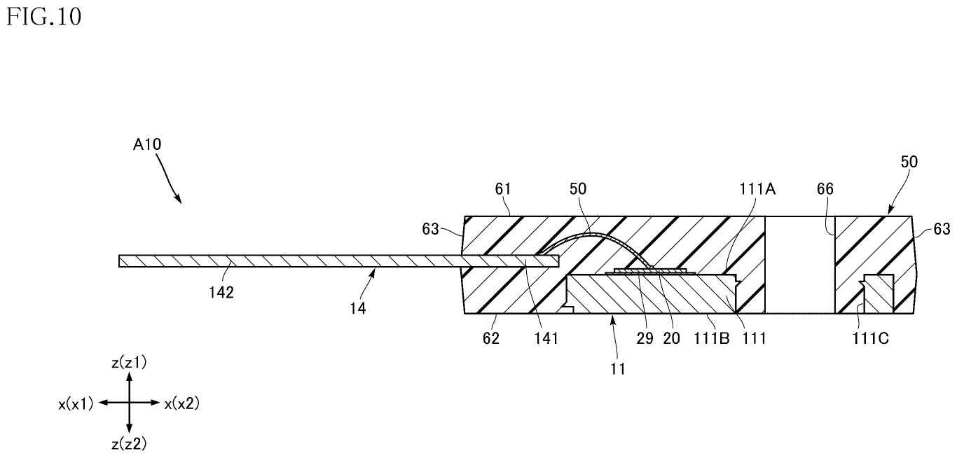

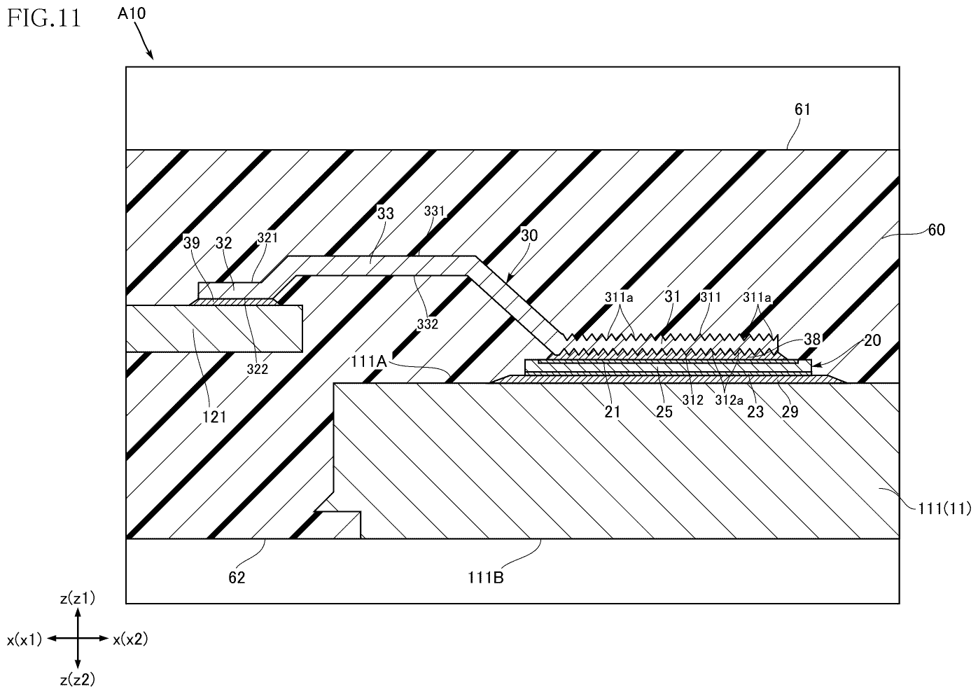

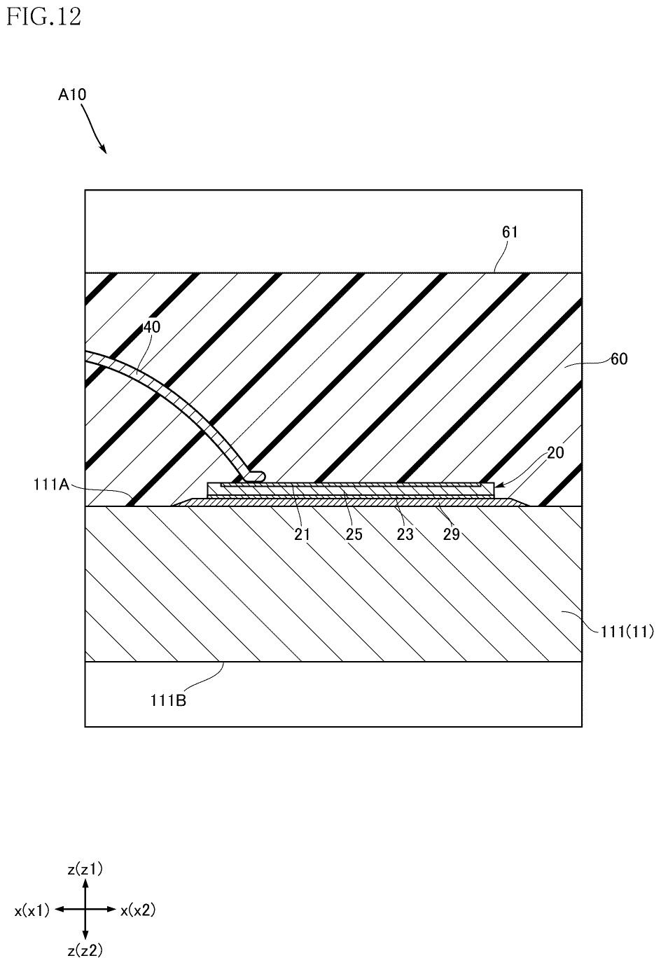

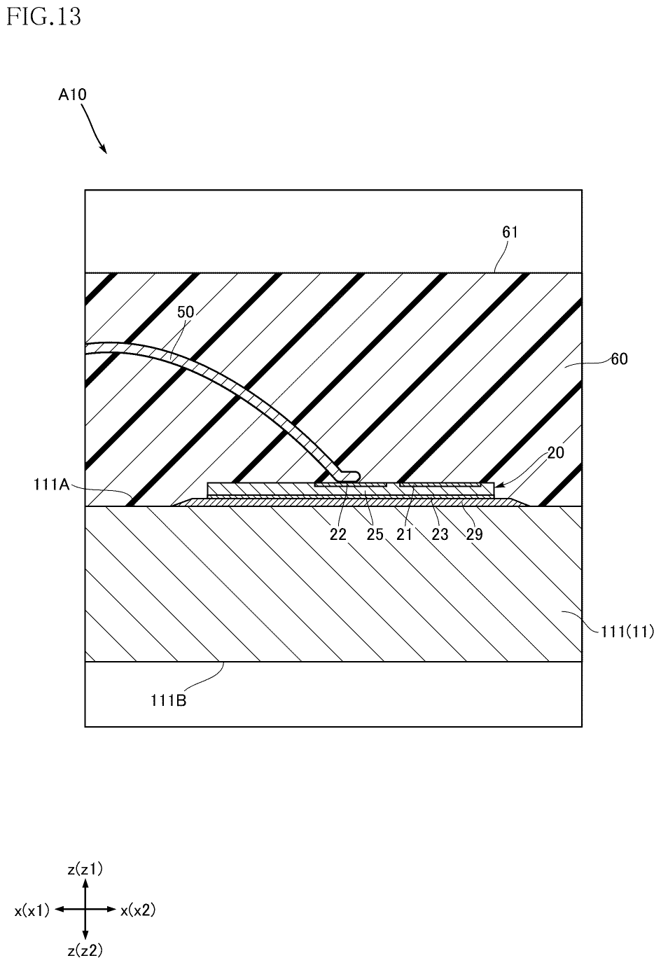

FIG. 1 is a perspective view of the semiconductor device A10. FIG. 2 is a plan view of the semiconductor device A10. FIG. 3 is a plan view of a portion of the semiconductor device A10. In FIG. 3, the outline of the sealing resin 60 is indicated by imaginary lines (dash-double-dot line). FIG. 4 is a bottom view of the semiconductor device A10. FIG. 5 is a side view of the semiconductor device A10. FIG. 6 is a front view of the semiconductor device A10. FIG. 7 is a sectional view taken along line VII-VII in FIG. 3. FIG. 8 is a sectional view taken along line VIII-VIII in FIG. 3. FIG. 9 is a sectional view taken along line IX-IX in FIG. 3. FIG. 10 is a sectional view taken along line X-X in FIG. 3. FIG. 11 is an enlarged view of a portion of FIG. 8. FIG. 12 is an enlarged view of a portion of FIG. 9. FIG. 13 is an enlarged view of a portion of FIG. 10.

In these figures, the “thickness direction z” is an example of the thickness direction of the present disclosure. The “first direction x” is an example of a direction perpendicular to the thickness direction z. The “second direction y” is the direction perpendicular to both the thickness direction z and the first direction x. One side in the thickness direction z is an example of the “first side in the thickness direction” of the present disclosure and is designated as the “z1 side in the thickness direction z”. The other side in the thickness direction z is an example of the “second side in the thickness direction” of the present disclosure and is designated as the “z2 side in the thickness direction z”. An example of one side in the first direction x is the “x1 side in the first direction x”, and an example of the other side in the first direction x is the “x2 side in the first direction x.” An example of one side in the second direction y is the “y1 side in the second direction y”, and an example of the other side in the second direction y is the “y2 side in the second direction y.”

As shown in FIGS. 1 to 4 and 6 to 10, the first lead 11 includes a base portion 111 and a terminal portion 112. The first lead 11 is a conductive component that supports the semiconductor element 20 and forms a portion of a conduction path between the semiconductor element 20 and a wiring board (not shown) or the like when the semiconductor device A10 is mounted thereon. The first lead 11 is an example of the “first conductive support member” of the present disclosure.

The first lead 11 contains copper (Cu) or a copper alloy, for example. The first lead 11 may additionally include a surface metal layer, which is not shown in the figures. The surface metal layer contains Ag (silver) or Ni (nickel), for example.

The base portion 111 has a first obverse surface 111A, a first reverse surface 111B, and a through-hole 111C. The first obverse surface 111A faces the z1 side in the thickness direction z. The first reverse surface 111B faces the 22 side in the thickness direction z. The through-hole 111C extends through the base portion 111 in the thickness direction z. In the illustrated example, the through-hole 111C is circular as viewed in the thickness direction z, although the shape of is not specifically limited.

The terminal portion 112 is connected to the base portion 111 and includes a part extending toward the x1 side in the first direction x. The base portion 111 and the terminal portion 112 are electrically connected to each other. The terminal portion 112 is partially covered with the scaling resin 60. The part of the terminal portion 112 covered with the sealing resin 60 is bent as viewed in the second direction y. The surface of the terminal portion 112 that is exposed from the sealing resin 60 may be coated with Sn plating.

As shown in FIGS. 1 to 4, 6, and 8, the second lead 12 is spaced apart from the first lead 11 and positioned on the y2 side in the second direction y with respect to the terminal portion 112 of the first lead 11. With respect to the base portion 111 of the first lead 11, the second lead 12 is positioned on the x1 side in the first direction x. The second lead 12 is electrically connected to the semiconductor element 20 via the first conductive member 30. The second lead 12 is an example of the “second conductive support member” of the present disclosure. The second lead 12 includes a pad portion 121 and a terminal portion 122. The pad portion 121 is covered with the scaling resin 60. The pad portion 121 may be plated with silver (Ag) or tin (Sn), for example. The terminal portion 122 is connected to the pad portion 121. The terminal portion 122 is partially covered with the scaling resin 60 and partially exposed from the sealing resin 60. The terminal portion 122 extends in the first direction x, in parallel with the terminal portion 112, for example. The terminal portion 122 may have a surface plated with tin (Sn), for example.

As shown in FIGS. 1 to 4, 6, and 9, the third lead 13 is spaced apart from the first lead 11 and the second lead 12 and positioned on the y2 side in the second direction y with respect to the second lead 12. The third lead 13 is adjacent to the second lead 12 in the second direction y. With respect to the base portion 111, the third lead 13 is positioned on the x1 side in the first direction x. The third lead 13 is electrically connected to the semiconductor element 20 via the second conductive member 40. The third lead 13 is an example of the “third conductive support member” of the present disclosure. The third lead 13 includes a pad portion 131 and a terminal portion 132. The pad portion 131 is covered with the scaling resin 60. The pad portion 131 may be plated with silver (Ag) or tin (Sn), for example. The terminal portion 132 is connected to the pad portion 131. The terminal portion 132 is partially covered with the sealing resin 60 and partially exposed from the sealing resin 60. The terminal portion 132 extends in the first direction x, in parallel with the terminal portions 112 and 122, for example. The terminal portion 132 may have a surface plated with tin (Sn), for example.

As shown in FIGS. 1 to 4, 6, and 10, the fourth lead 14 is spaced apart from the first lead 11, the second lead 12, and the third lead 13 and positioned on the y2 side in the second direction y with respect to the third lead 13. In the second direction y, the fourth lead 14 is positioned on the side of the third lead 13 opposite the second lead 12. With respect to the base portion 111, the fourth lead 14 is positioned on the x1 side in the first direction x. The fourth lead 14 is electrically connected to the semiconductor element 20 via the third conductive member 50. The fourth lead 14 is an example of the “fourth conductive support member” of the present disclosure. The fourth lead 14 includes a pad portion 141 and a terminal portion 142. The pad portion 141 is covered with the sealing resin 60. The pad portion 141 may be plated with silver (Ag) or tin (Sn), for example. The terminal portion 142 is connected to the pad portion 141. The terminal portion 142 is partially covered with the sealing resin 60 and partially exposed from the sealing resin 60. The terminal portion 142 extends in the first direction x, in parallel with the terminal portions 112, 122, and 132, for example. The terminal portion 142 may have a surface plated with tin (Sn), for example.

As shown in FIGS. 3 and 8 to 13, the semiconductor element 20 is mounted on the first obverse surface 111A of the base portion 111. In the semiconductor device A10, the configuration of the semiconductor element 20 is not specifically limited. In the present embodiment, the semiconductor element 20 is a switching element, such as an n-channel vertical MOSFET (metal-oxide-semiconductor field-effect transistor). The semiconductor element 20 is not limited to a MOSFET. In another example, the semiconductor element 20 may be other types of transistors, such as IGBT (insulated gate bipolar transistor). In a yet another example, the semiconductor element 20 may be an LSI (large scale integration) or a diode. As viewed in the thickness direction z, the semiconductor element 20 is rectangular. The semiconductor element 20 is positioned at the center of the base portion 111 in the second direction y.

The semiconductor element 20 includes a semiconductor layer 25, a first electrode 21, a second electrode 22, and a third electrode 23. The thickness (the dimension in the thickness direction z) of the semiconductor element 20 is not specifically limited and may range approximately from 100 μm to 1000 μm, for example.

The semiconductor layer 25 includes a compound semiconductor substrate. The primary material of the compound semiconductor substrate is silicon carbide (SiC). In another example, the primary material of the compound semiconductor substrate may be silicon (Si).

The first electrode 21 is disposed on the z1 side of the semiconductor layer 25 in the thickness direction z. The first electrode 21 carries a current corresponding to the power converted by the semiconductor element 20. In the present embodiment, the first electrode 21 serves as the source electrode.

The second electrode 22 is disposed on the z1 side of the semiconductor layer 25 in the thickness direction z. The second electrode 22 is spaced apart from the first electrode 21. The second electrode 22 receives voltage for driving the semiconductor element 20. In the present embodiment, the second electrode 22 serves as the gate electrode. As viewed in the thickness direction z, the second electrode 22 has a smaller area than the first electrode 21. In the illustrated example, as viewed in the thickness direction z, the position of the second electrode 22 on the semiconductor element 20 is offset toward the y2 side in the second direction y and is centered along the first direction x. The first electrode 21 covers most of the semiconductor layer 25 on the z1 side in the thickness direction z, except for the region where the second electrode 22 is disposed.

The third electrode 23 is disposed on the 22 side of the semiconductor layer 25 in the thickness direction z. The third electrode 23 faces the first obverse surface 111A of the base portion 111 of the first lead 11. The third electrode 23 carries a current corresponding to the power to be converted by the semiconductor element 20. In the present embodiment, the third electrode 23 serves as the drain electrode. The third electrode 23 is electrically bonded to the first obverse surface 111A via a bonding layer 29. The bonding layer 29 is made of a conductive material, such as solder or Ag (silver) paste.

The first lead 11 is electrically connected to the third electrode 23 of the semiconductor element 20. The terminal portion 112 serves as the drain terminal of the semiconductor device A10. The second lead 12 is electrically connected to the first electrode 21 of the semiconductor element 20. The terminal portion 122 serves as the source terminal of the semiconductor device A10. The third lead 13 is electrically connected to the first electrode 21 of the semiconductor element 20. The terminal portion 132 serves as the source sense terminal of the semiconductor device A10. The fourth lead 14 is electrically connected to the second electrode 22 of the semiconductor element 20. The terminal portion 142 serves as the gate terminal of the semiconductor device A10.

As shown in FIGS. 3, 8, and 11, the first conductive member 30 is electrically bonded to the first electrode 21 of the semiconductor element 20 and also to the pad portion 121 of the second lead 12. The first conductive member 30 is made from a metal plate, for example. The constituent material of the first conductive member 30 includes copper (Cu), for example. The first conductive member 30 is a metal plate with appropriate bends. In the illustrated example, the first conductive member 30 is a Cu clip (metal clip) of a predetermined length. The first conductive member 30 extends longitudinally in the first direction x. The first conductive member 30 has a pair of side surfaces 30A and 30B. The side surfaces 30A and 30B face in a direction perpendicular to the thickness direction z. In the present embodiment, the side surfaces 30A and 30B face in the second direction y. The side surface 30A faces the y2 side in the second direction y, and the side surface 30B faces the y1 side in the second direction y. The thickness of the first conductive member 30 (the dimension in the thickness direction z) is not specifically limited and may range approximately from 150 μm to 250 μm, for example.

The first conductive member 30 includes a first portion 31, a second portion 32, and a first intermediate portion 33.

The first portion 31 is bonded to the first electrode 21 via a first bonding layer 38, electrically connecting the first conductive member 30 to the first electrode 21. The first bonding layer 38 is made of a conductive material, such as solder or Ag (silver) paste. In the illustrated example, the first portion 31 is positioned at the end of the first conductive member 30 on the x2 side in the first direction x. The first portion 31 is rectangular as viewed in the thickness direction 2.

The first portion 31 has a first surface 311 and a second surface 312. The first surface 311 faces the z1 side in the thickness direction z. The second surface 312 faces the 22 side in the thickness direction z. The first portion 31 is formed with a plurality of first recesses 311a and a plurality of second recesses 312a.

The first recesses 311a are recessed from the first surface 311 toward the 22 side in the thickness direction z. In the present embodiment, the first recesses 311a are composed of a plurality of grooves that are arranged along a direction perpendicular to the thickness direction z, with each groove extending linearly. In the illustrated example, the first recesses 311a are arranged along the first direction x, and each first recess 311a extends linearly in the second direction y. As viewed in the second direction y, the first recesses 311a are positioned consecutively in the first direction x without spacing. The first recesses 311a are formed by pressing, for example. Note, however, that the arrangement of the first recesses 311a is not limited to the illustrated example. Alternatively, the first recesses 311a may be arranged along the second direction y, with each first recess 311a extending linearly in the first direction x. The process for forming the first recesses 311a is not limited to the pressing mentioned above. Alternatively, a laser process or a chemical process (such as etching) may be used, for example. The depth of the first recesses 311a (the dimension in the thickness direction z) can be set as appropriate. The process for forming the first recesses 311a may be selected based on the desired depth of the first recesses 311a. In the illustrated example, the first recesses 311a are formed across substantially the entire first surface 311. In a different example, however, the first recesses 311a may be formed on a limited portion of the first surface 311. In the present embodiment, each first recess 311a has a triangular cross-sectional shape, which defines the serrated profile of the first surface 311. In a different example, however, the cross-sectional shape of the first recesses 311a is not limited to such. In addition, the first recesses 311a are not limited to grooves. For example, the first recesses 311a may be features that are dotted or scattered as viewed in the thickness direction z.

The second recesses 312a are recessed from the second surface 312 toward the z1 side in the thickness direction z. In the present embodiment, the second recesses 312a are composed of a plurality of grooves that are arranged along a direction perpendicular to the thickness direction z, with each groove extending linearly. In the illustrated example, the second recesses 312a are arranged along the first direction x, and each second recess 312a extends linearly in the second direction y. As viewed in the second direction y, the second recesses 312a are positioned consecutively in the first direction x without spacing. In the illustrated example, the second recesses 312a have the same shape and dimension as the first recesses 311a described above. The second recesses 312a are formed by pressing, for example. Note, however, that the arrangement of the second recesses 312a is not limited to the illustrated example. Alternatively, the second recesses 312a may be arranged along the second direction y, with each second recess 312a extending linearly in the first direction x. The process for forming the second recesses 312a is not limited to the pressing mentioned above. Alternatively, a laser process or a chemical process (such as etching) may be used, for example. The depth of the second recesses 312a (the dimension in the thickness direction z) can be set as appropriate. The process for forming the second recesses 312a may be selected based on the desired depth of the second recesses 312a. In the illustrated example, the second recesses 312a are formed across substantially the entire second surface 312. In a different example, however, the second recesses 312a may be formed on a limited portion of the second surface 312. In the present embodiment, each second recess 312a has a triangular cross-sectional shape, which defines the serrated profile of the second surface 312. In a different example, however, the cross-sectional shape of each second recess 312a is not limited to such. In addition, the second recesses 312a are not limited to grooves. For example, the second recesses 312a may be features that are dotted or scattered as viewed in the thickness direction z.

The second portion 32 is bonded to the pad portion 121 of the second lead 12 via a second bonding layer 39, electrically connecting the first conductive member 30 to the second lead 12. The second bonding layer 39 is made of a conductive material, such as solder or Ag (silver) paste. In the illustrated example, the second portion 32 is positioned at the end of the first conductive member 30 on the x1 side in the first direction x. The second portion 32 is rectangular as viewed in the thickness direction z.

The second portion 32 has a third surface 321 and a fourth surface 322. The third surface 321 faces the z1 side in the thickness direction z. The fourth surface 322 faces the 22 side in the thickness direction z.

As viewed in the thickness direction z, the first intermediate portion 33 is positioned between the first portion 31 and the second portion 32. The first intermediate portion 33 connects the first portion 31 and the second portion 32. The first intermediate portion 33 is rectangular as viewed in the thickness direction z. As viewed in the second direction y, the first intermediate portion 33 is bent at the sections where it connects to the first portion 31 and the second portion 32. The section of the first intermediate portion 33, excluding the bent sections, lies parallel to the xy plane and is positioned further on the z1 side than the first portion 31 and the second portion 32.

The first intermediate portion 33 has a fifth surface 331 and a sixth surface 332. The fifth surface 331 faces the z1 side in the thickness direction z. The sixth surface 332 faces the z2 side in the thickness direction z.

As shown in FIGS. 3, 9, and 12, the second conductive member 40 is electrically bonded to the first electrode 21 of the semiconductor element 20 and also to the pad portion 131 of the third lead 13. In the present embodiment, the second conductive member 40 is a bonding wire. The configuration of the second conductive member 40 is not specifically limited, and the second conductive member 40 may have circular, elliptical, and flat rectangular cross sections, for example. In the illustrated example, the second conductive member 40 has a circular cross section. The second conductive member 40 may be bonded by wedge bonding. The material of the second conductive member 40 is not specifically limited, and examples include copper (Cu) and aluminum (Al).

As shown in FIGS. 3, 10, and 13, the third conductive member 50 is electrically bonded to the second electrode 22 of the semiconductor element 20 and the pad portion 141 of the fourth lead 14. In the present embodiment, the third conductive member 50 is a bonding wire. The configuration of the third conductive member 50 is not specifically limited, and the third conductive member 50 may have circular, elliptical, and flat rectangular cross sections. In the illustrated example, the third conductive member 50 has a circular cross section. The third conductive member 50 may be bonded by wedge bonding. The material of the third conductive member 50 is not specifically limited, and examples include copper (Cu) and aluminum (Al).

The bonding layer 29, the first bonding layer 38, and the second bonding layer 39 are all bonded simultaneously by, for example, reflow soldering, respectively to the base portion 111 of the semiconductor element 20, the first electrode 21 of the first conductive member 30, and the second lead 12 (the pad portion 121). The second conductive member 40 and the third conductive member 50 are bonded after the first conductive member 30 is bonded.

As shown in FIGS. 1 to 10, the sealing resin 60 fully covers the semiconductor element 20, the first conductive member 30, the second conductive member 40, and the third conductive member 50, and partially covers the first lead 11, the second lead 12, the third lead 13, and the fourth lead 14. The sealing resin 60 is electrically insulating. The sealing resin 60 is made of material, containing, for example, black epoxy resin. The sealing resin 60 has a resin obverse surface 61, a resin reverse surface 62, a pair of first resin side surfaces 63, a pair of second resin side surfaces 64, a pair of openings 65, a mounting hole 66, and a recessed portion 67.

The resin obverse surface 61 faces the z1 side in the thickness direction z. The resin reverse surface 62 faces the 22 side in the thickness direction z. The first reverse surface 111B of the base portion 111 is exposed from the resin reverse surface 62. The first reverse surface 111B and the resin reverse surface 62 are flush with each other.

The first resin side surfaces 63 are spaced apart from each other in the first direction x. Each first resin side surface 63 is connected to the resin obverse surface 61 and the resin reverse surface 62. The first resin side surface 63 facing the x1 side in the first direction x is the location from which the terminal portions protrude, namely the terminal portion 112 of the first lead 11, the terminal portion 122 of the second lead 12, the terminal portion 132 of the third lead 13, and the terminal portion 142 of the fourth lead 14.

The second resin side surfaces 64 are spaced apart from each other in the second direction y. Each second resin side surface 64 is connected to the resin obverse surface 61 and the resin reverse surface 62.

The openings 65 are spaced apart from each other in the second direction y. Each opening 65 is recessed inward of the sealing resin 60 from the resin obverse surface 61 and also from one of the second resin side surfaces 64. Portions of the first obverse surface 111A of the base portion 111 of the first lead 11 are exposed through the openings 65.

The mounting hole 66 extends from the resin obverse surface 61 to the resin reverse surface 62, passing through the sealing resin 60 in the thickness direction z. As viewed in the thickness direction z, the mounting hole 66 is contained within the through-hole 111C in the base portion 111 of the first lead 11. The inner peripheral surface of the base portion 111 defining the through-hole 111C is covered with the sealing resin 60. Thus, as viewed in the thickness direction z, the maximum size of the mounting hole 66 is smaller than the size of the through-hole 111C.

The recessed portion 67 is positioned between the terminal portions 112 and 122 in the second direction y. The recessed portion 67 is recessed from the first resin side surface 63 that is positioned on the x1 side in the first direction x, toward the x2 side in the first direction x.

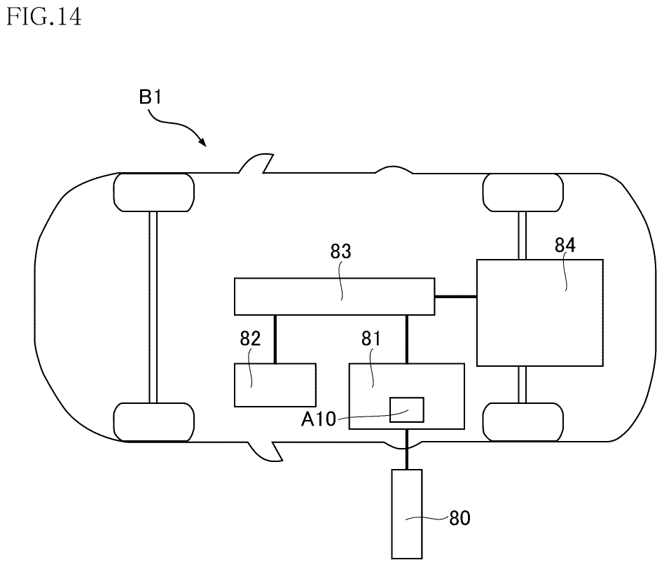

The following describes an example of how the semiconductor device A10 is used, with reference to FIG. 14. FIG. 14 is a schematic diagram of a vehicle B1 provided with the semiconductor device A10. The vehicle B1 is an electric vehicle (EV), for example.

As shown in FIG. 14, the vehicle B1 includes an AC-DC conversion device B1, a power receiving device B2, a storage battery 83, and a drive system 84. The semiconductor device A10 forms a part of the AC-DC conversion device B1. When the vehicle B1 receives AC power from a charging station 80, which may be an outdoor AC source, the AC-DC conversion device B1 converts it to high-voltage DC power. The AC-DC conversion device B1 charges the storage battery 83 with the resulting high-voltage DC power. The power receiving device B2 utilizes a non-contact charging system to charge the storage battery 83 via electromagnetic induction from a non-contact charger (not shown), which may be installed in a parking lot, for example. The power stored in the storage battery 83 is supplied to the drive system 84, which consists of an inverter, an AC motor, and a transmission. The drive system 84 drives the vehicle B1. The AC-DC conversion device B1 is an example of the “power conversion device” of the present disclosure. The following describes the operation of the semiconductor device A10.

The semiconductor device A10 includes the first conductive member 30 that is electrically bonded to the first electrode 21 of the semiconductor element 20 and to the second lead 12. The first conductive member 30 includes the first portion 31 that is bonded to the first electrode 21 via the conductive first bonding layer 38. The first portion 31 has the first surface 311 and the second surface 312 respectively facing the z1 side and the 22 side in the thickness direction z. The first portion 31 has the first recesses 311a on the first surface 311, and the second recesses 312a on the second surface 312. Due to the first recesses 311a, the first surface 311 of the first portion 31 has an uneven surface profile. The first surface 311 is in contact with the sealing resin 60, thereby producing an anchoring effect that improves the bond between the first portion 31 (the first conductive member 30) and the scaling resin 60. Due to the second recesses 312a, the second surface 312 of the first portion 31 also has an uneven surface profile. The second surface 312 is in contact with the first bonding layer 38, thereby producing an anchoring effect that improves the bond between the first portion 31 (the first conductive member 30) and the first bonding layer 38. This improves the reliability of the semiconductor device A10.

The first recesses 311a are composed of a plurality of, linearly extending grooves that are arranged along the first direction x, which is perpendicular to the thickness direction z. The second recess 312a are composed of a plurality of, linearly extending grooves that are arranged along the first direction x, which is perpendicular to the thickness direction z. With this configuration, the anchoring effect produced by the uneven surface profiles of the first surface 311 and the second surface 312 is further enhanced. This is favorable for improving the adhesion between the first portion 31 (the first conductive member 30) and the sealing resin 60, as well as the bond between the first portion 31 (the first conductive member 30) and the first bonding layer 38.

With the first recesses 311a composed of a plurality of grooves that are arranged along the first direction x, the surface area of the first surface 311 is efficiently increased. This leads to improved heat radiation from the surface of the first conductive member 30.

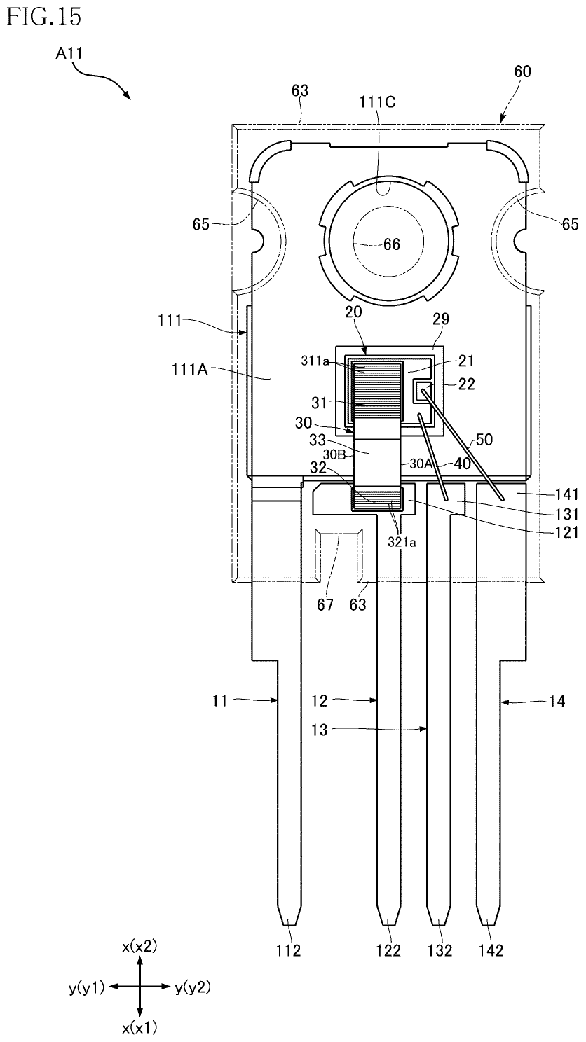

FIGS. 15 to 25 show variations and other embodiments of the present disclosure. In these figures, elements that are identical or similar to those of the embodiment described above are indicated by the same reference numerals, and redundant descriptions are omitted. In addition, the configurations of elements and components in the embodiments and variations described below may be combined in any manner, provided that no technical inconsistencies arise.

### First Variation of First Embodiment

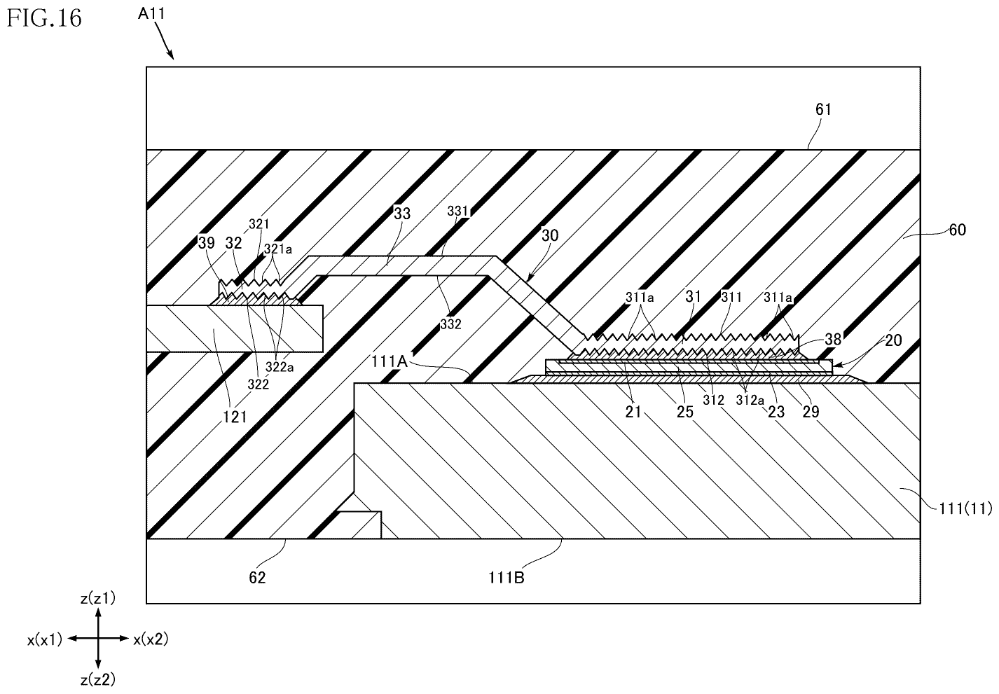

FIGS. 15 and 16 show a first variation of the semiconductor device A10. FIG. 15 is a plan view of a portion of a semiconductor device A11 according to the first variation. FIG. 16 is an enlarged sectional view of a portion of the semiconductor device A11, with the section corresponding to that shown in FIG. 11. In FIG. 15, the outline of the sealing resin 60 is indicated by imaginary lines (dash-double-dot line). The semiconductor device A11 of this variation differs from the semiconductor device A10 in the configuration of the first conductive member 30.

In this variation, the second portion 32 of the first conductive member 30 is formed with a plurality of third recesses 321a and a plurality of fourth recesses 322a. The third recesses 321a are recessed from the third surface 321 toward the 22 side in the thickness direction z. The third recesses 321a are arranged along the first direction x, and each third recess 321a extends linearly in the second direction y. The fourth recesses 322a are recessed from the fourth surface 322 toward the z1 side in the thickness direction z. The fourth recesses 322a are arranged along the first direction x, and each fourth recess 322a extends linearly in the second direction y. The third recesses 321a are similar in configuration to the first recesses 311a, and the fourth recesses 322a are similar in configuration to the second recesses 312a.

The semiconductor device A11 is configured such that the first surface 311 of the first portion 31 has an uneven surface profile defined by the first recesses 311a. The first surface 311 is in contact with the sealing resin 60, thereby producing an anchoring effect that improves the bond between the first portion 31 (the first conductive member 30) and the scaling resin 60. In addition, the second surface 312 of the first portion 31 has an uneven surface profile defined by the second recesses 312a. The second surface 312 is in contact with the first bonding layer 38, thereby producing an anchoring effect that improves the bond between the first portion 31 (the first conductive member 30) and the first bonding layer 38. This improves the reliability of the semiconductor device A11.

The first recesses 311a are composed of a plurality of, linearly extending grooves that are arranged along the first direction x, which is perpendicular to the thickness direction z. The second recess 312a are composed of a plurality of, linearly extending grooves that are arranged along the first direction x, which is perpendicular to the thickness direction z. With this configuration, the anchoring effect produced by the uneven surface profiles of the first surface 311 and the second surface 312 is further enhanced, improving the adhesion between the first portion 31 (the first conductive member 30) and the sealing resin 60, as well as the bond between the first portion 31 (the first conductive member 30) and the first bonding layer 38.

With the first recesses 311a composed of a plurality of grooves that are arranged along the first direction x, the surface area of the first surface 311 is efficiently increased. This leads to improved heat radiation from the surface of the first conductive member 30.

In the variation, the second portion 32 of the first conductive member 30 also has the third recesses 321a on the third surface 321 and the fourth recesses 322a on fourth surface 322. The third surface 321 of the second portion 32 has an uneven surface profile defined by the third recesses 321a. The third surface 321 is in contact with the sealing resin 60, thereby producing an anchoring effect that improves the bond between the second portion 32 (the first conductive member 30) and the sealing resin 60. The fourth surface 322 of the second portion 32 also has an uneven surface profile defined by the fourth recesses 322a. The fourth surface 322 is in contact with the second bonding layer 39, thereby producing an anchoring effect that improves the bond between the second portion 32 (the first conductive member 30) and the second bonding layer 39. This improves the reliability of the semiconductor device A11.

The third recesses 321a are composed of a plurality of, linearly extending grooves that are arranged along the first direction x, which is perpendicular to the thickness direction z. The fourth recesses 322a are composed of a plurality of linearly extending grooves that are arranged along the first direction x, which is perpendicular to the thickness direction z. With this configuration, the anchoring effect produced by the uneven surface profiles of the third surface 321 and the fourth surface 322 is further enhanced. This is favorable for improving the adhesion between the second portion 32 (the first conductive member 30) and the sealing resin 60, as well as the bond between the second portion 32 (the first conductive member 30) and the second bonding layer 39.

With the third recesses 321a composed of a plurality of grooves that are arranged along the first direction x, the surface area of the third surface 321 is efficiently increased. This leads to improved heat radiation from the surface of the first conductive member 30.

### Second Variation of First Embodiment

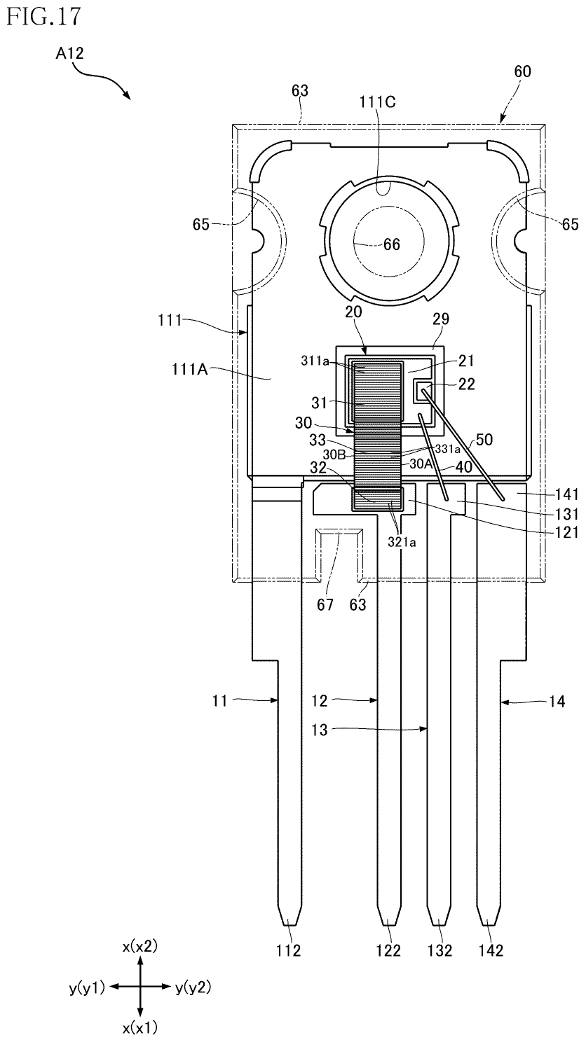

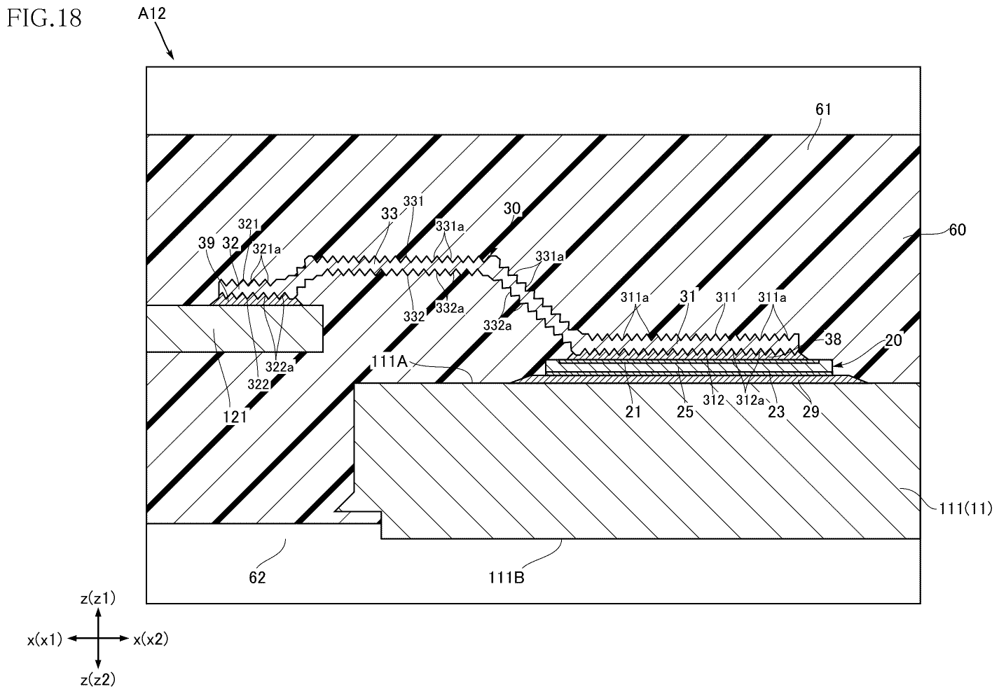

FIGS. 17 and 18 show a second variation of the semiconductor device A10. FIG. 17 is a plan view of a portion of a semiconductor device A12 according to the second variation. FIG. 18 is an enlarged sectional view of a portion of the semiconductor device A12, with the section corresponding to that shown in FIG. 11. In FIG. 17, the outline of the sealing resin 60 is indicated by imaginary lines (dash-double-dot line). The semiconductor device A12 of this variation differs from the semiconductor devices A10 and A11 in the configuration of the first conductive member 30.

The semiconductor device A12 differs from the semiconductor device A11 in the configuration of the first intermediate portion 33 of the first conductive member 30. In this variation, the first intermediate portion 33 is formed with a plurality of fifth recesses 331a and a plurality of sixth recesses 332a. The fifth recesses 331a are recessed from the fifth surface 331. The fifth recesses 331a are arranged along the first direction x, and each fifth recess 331a extends linearly in the second direction y. The sixth recesses 332a are recessed from the sixth surface 332. The sixth recesses 332a are arranged along the first direction x, and each sixth recess 332a extends linearly in the second direction y. The fifth recesses 331a are similar in configuration to the first recesses 311a, and the sixth recesses 332a are similar in configuration to the second recesses 312a.

The semiconductor device A12 is configured such that the first surface 311 of the first portion 31 has an uneven surface profile defined by the first recesses 311a. The first surface 311 is in contact with the sealing resin 60, thereby producing an anchoring effect that improves the bond between the first portion 31 (the first conductive member 30) and the sealing resin 60. In addition, the second surface 312 of the first portion 31 has an uneven surface profile defined by the second recesses 312a. The second surface 312 is in contact with the first bonding layer 38, thereby producing an anchoring effect that improves the bond between the first portion 31 (the first conductive member 30) and the first bonding layer 38. This improves the reliability of the semiconductor device A12. Additionally, the semiconductor device A12 achieves the same operation and effects as the semiconductor device A11 described above.

In the variation, in addition, the first intermediate portion 33 of the first conductive member 30 is formed with the fifth recesses 331a on the fifth surface 331 and the sixth recesses 332a on the sixth surface 332. Thus, the fifth surface 331 of first intermediate portion 33 has an uneven surface profile defined by the fifth recesses 331a, and the sixth surface 332 has a uneven surface profile defined by the sixth recesses 332a. The fifth surface 331 and the sixth surface 332 are both in contact with the sealing resin 60, thereby producing an anchoring effect that improves the bond between the first intermediate portion 33 (the first conductive member 30) and the sealing resin 60. This improves the reliability of the semiconductor device A12.

The fifth recesses 331a are composed of a plurality of, linearly extending grooves that are arranged along the first direction x, which is perpendicular to the thickness direction z. The sixth recesses 332a are composed of a plurality of, linearly extending grooves that are arranged along the first direction x, which is perpendicular to the thickness direction z. With this configuration, the anchoring effect produced by the uneven surface profiles of the fifth surface 331 and the sixth surface 332 is further enhanced. This is favorable for improving the adhesion between the first intermediate portion 33 (the first conductive member 30) and the sealing resin 60.

With the fifth recesses 331a composed of a plurality of grooves that are arranged along the first direction x, the surface area of the fifth surface 331 is efficiently increased. This leads to improved heat radiation from the surface of the first conductive member 30.

### Third Variation of First Embodiment

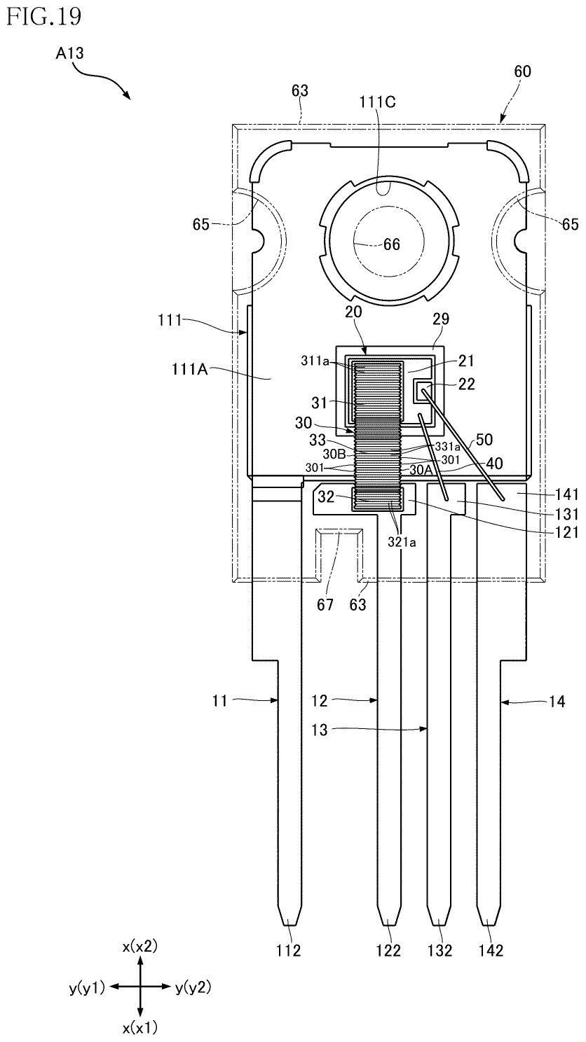

FIG. 19 shows a third variation of the semiconductor device A10. FIG. 19 is a plan view of a portion of the semiconductor device A13 according to the third variation. In FIG. 19, the outline of the sealing resin 60 is indicated by imaginary lines (dash-double-dot line). The semiconductor device A13 of this variation differs from the semiconductor device A12 in the configuration of the first conductive member 30.

The first conductive member 30 of the semiconductor device A13 is formed with a plurality of seventh recesses 301. The seventh recesses 301 are recessed from the side surfaces 30A and 30B of the first conductive member 30. In the illustrated example, the first conductive member 30 includes a plurality of seventh recesses 301 that are recessed from the side surface 30A toward the y1 side in the second direction y, and a plurality of seventh recesses 301 that are recessed from the side surface 30B toward the y2 side in the second direction y. In the illustrated example, the seventh recesses 301 are composed of a plurality of grooves arranged along the first direction x.

The semiconductor device A13 is configured such that the first surface 311 of the first portion 31 has an uneven surface profile defined by the first recesses 311a. The first surface 311 is in contact with the sealing resin 60, thereby producing an anchoring effect that improves the bond between the first portion 31 (the first conductive member 30) and the sealing resin 60. In addition, the second surface 312 of the first portion 31 has an uneven surface profile defined by the second recesses 312a. The second surface 312 is in contact with the first bonding layer 38, thereby producing an anchoring effect that improves the bond between the first portion 31 (the first conductive member 30) and the first bonding layer 38. This improves the reliability of the semiconductor device A13. Additionally, the semiconductor device A13 achieves the same operation and effects as the semiconductor device A12 described above.

In this variation, in addition, the first conductive member 30 is formed with the seventh recesses 301 that are recessed from the side surfaces 30A and 30B. Each of the side surfaces 30A and 30B of the first conductive member 30 has an uneven surface profiles defined by the seventh recesses 301. The side surfaces 30A and 30B are in contact with the sealing resin 60, thereby producing an anchoring effect that improves the bond between the first conductive member 30 and the sealing resin 60. This improves the reliability of the semiconductor device A13.

### Fourth Variation of First Embodiment

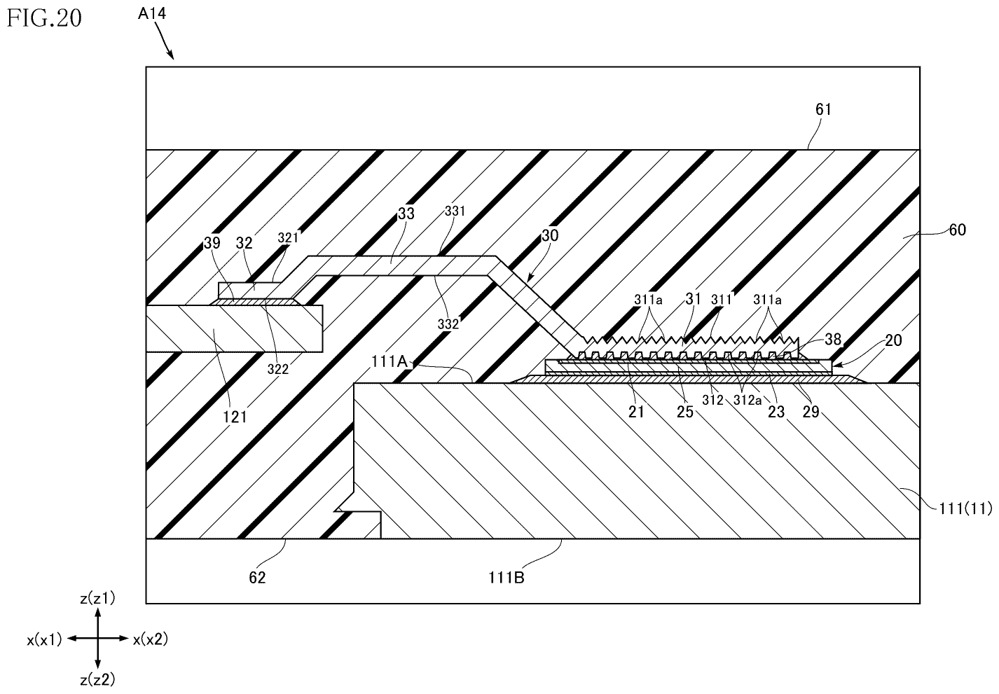

FIG. 20 shows a fourth variation of the semiconductor device A10. FIG. 20 is an enlarged sectional view of a portion of the semiconductor device A14 of the fourth variation, with the section corresponding to that shown in FIG. 11. The semiconductor device A14 of this variation differs from the semiconductor device A10 in the configuration of the first conductive member 30.

This variation differs from the semiconductor device A10 in the configuration of the second recesses 312a formed in the first portion 31 of the first conductive member 30. That is, the second recesses 312a each have a trapezoidal cross-sectional shape and, as viewed in the second direction y, are arranged at intervals in the first direction x. Thus, the second surface 312 includes portions in close proximity to the first electrode 21 with a slight gap therebetween, or portions in contact with the first electrode 21.

The semiconductor device A14 is configured such that the first surface 311 of the first portion 31 has an uneven surface profile defined by the first recesses 311a. The first surface 311 is in contact with the sealing resin 60, thereby producing an anchoring effect that improves the bond between the first portion 31 (the first conductive member 30) and the sealing resin 60. In addition, the second surface 312 of the first portion 31 has an uneven surface profile defined by the second recesses 312a. The second surface 312 is in contact with the first bonding layer 38, thereby producing an anchoring effect that improves the bond between the first portion 31 (the first conductive member 30) and the first bonding layer 38. This improves the reliability of the semiconductor device A14. Additionally, the semiconductor device A14 achieves the same operation and effects as the semiconductor device A10 described above.

### Second Embodiment

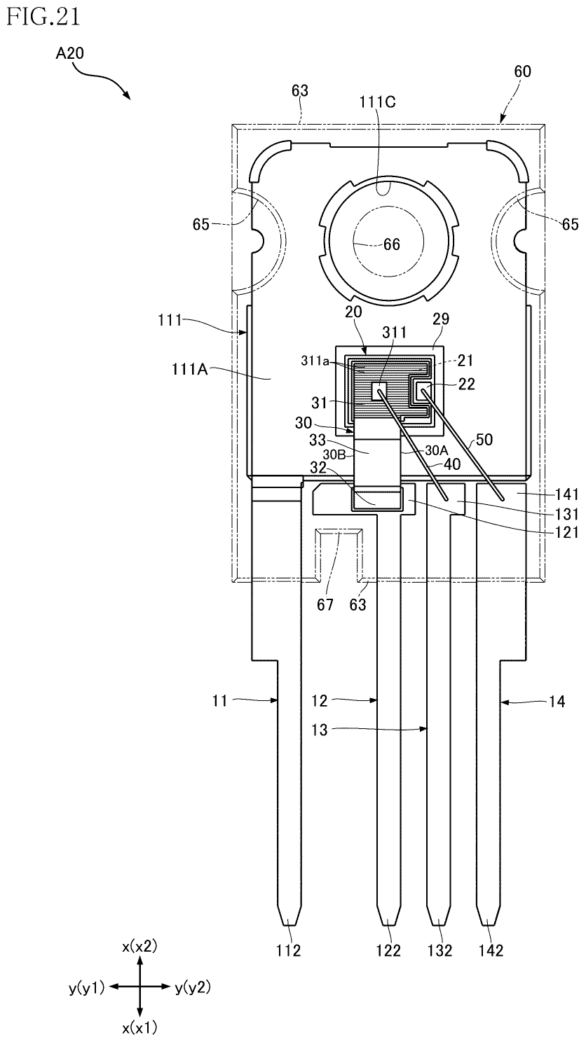

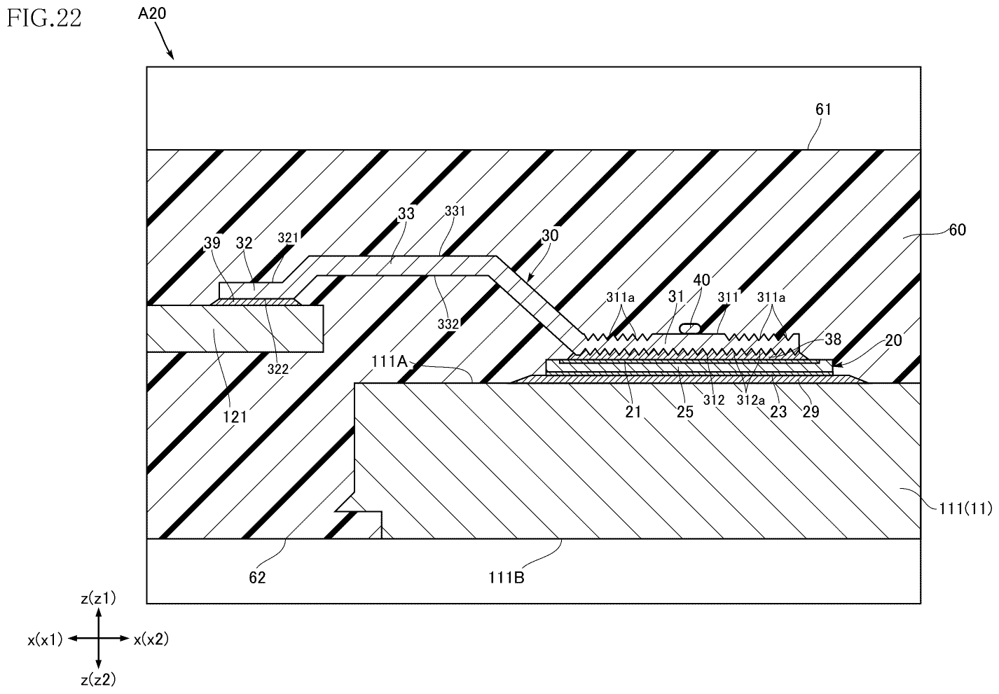

FIGS. 21 and 22 show a semiconductor device according to a second embodiment of the present disclosure. FIG. 21 is a plan view of a portion of a semiconductor device A20 according to the second embodiment of the present disclosure. FIG. 22 is an enlarged sectional view of a portion of the semiconductor device A20, with the section corresponding to that shown in FIG. 11. In FIG. 21, the outline of the sealing resin 60 is indicated by imaginary lines (dash-double-dot line). The semiconductor device A20 of the present embodiment differs from the semiconductor device A10 described above in the configuration of the first conductive member 30 and the arrangement of the second conductive member 40.

In the present embodiment, the second conductive member 40 is electrically bonded to the first portion 31 of the first conductive member 30 and the pad portion 131 of the third lead 13. The second conductive member 40 is electrically connected to the first electrode 21 of the semiconductor element 20 via the first conductive member 30 (the first portion 31). The first portion 31 has no first recesses 311a in the central region of the first surface 311 along the first direction x and the second direction y as viewed in the thickness direction z. The second conductive member 40 is bonded to this region (the central region along the first direction x and the second direction y) of the first surface 311 where no first recesses 311a are formed. As viewed in the thickness direction z, the first recesses 311a are formed around the region of the first portion 31 where the second conductive member 40 is bonded. Thus, as viewed in the thickness direction z, the first recesses 311a are arranged to occupy an annular region that surrounds the region where the first portion 31 and the second conductive member 40 are bonded.

In the present embodiment, the first portion 31 has a U-shape as viewed in the thickness direction z, with its legs extending along opposite sides of the second electrode 22 in the first direction x. Hence, the first portion 31 overlaps with most of the first electrode 21 as viewed in the thickness direction z. As viewed in the thickness direction z, the first recesses 311a are also formed on the legs of the first portion 31, which extend along opposite sides of the second electrode 22 in the first direction x.

The semiconductor device A20 is configured such that the first portion 31 is formed with the first recesses 311a defining an uneven surface profile of the first surface 311. The first surface 311 is in contact with the sealing resin 60, thereby producing an anchoring effect that improves the bond between the first portion 31 (the first conductive member 30) and the scaling resin 60. In addition, the second surface 312 of the first portion 31 also has an uneven surface profile defined by the second recesses 312a. The second surface 312 is in contact with the first bonding layer 38, thereby producing an anchoring effect that improves the bond between the first portion 31 (the first conductive member 30) and the first bonding layer 38. This improves the reliability of the semiconductor device A20. Additionally, the semiconductor device A20 achieves the same operation and effects as the semiconductor device A10 described above.

Furthermore, the semiconductor device A20 is configured such that the second conductive member 40 is electrically bonded to the first portion 31 (the first conductive member 30) and the third lead 13. The second conductive member 40 is electrically connected to the first electrode 21 via the first conductive member 30. In the present embodiment, no space needs to be provided for a bonding tool to bond the second conductive member 40 to the first electrode 21. This allows the first portion 31 to have a larger area as viewed in the thickness direction z, and also allows the first recesses 311a and the second recesses 312a to be formed over a larger areas. With this configuration, the anchoring effect produced by the first recesses 311a and the second recesses 312a is further enhanced, improving the adhesion between the first portion 31 (the first conductive member 30) and the sealing resin 60, as well as the bond between the first portion 31 (the first conductive member 30) and the first bonding layer 38.

### Third Embodiment

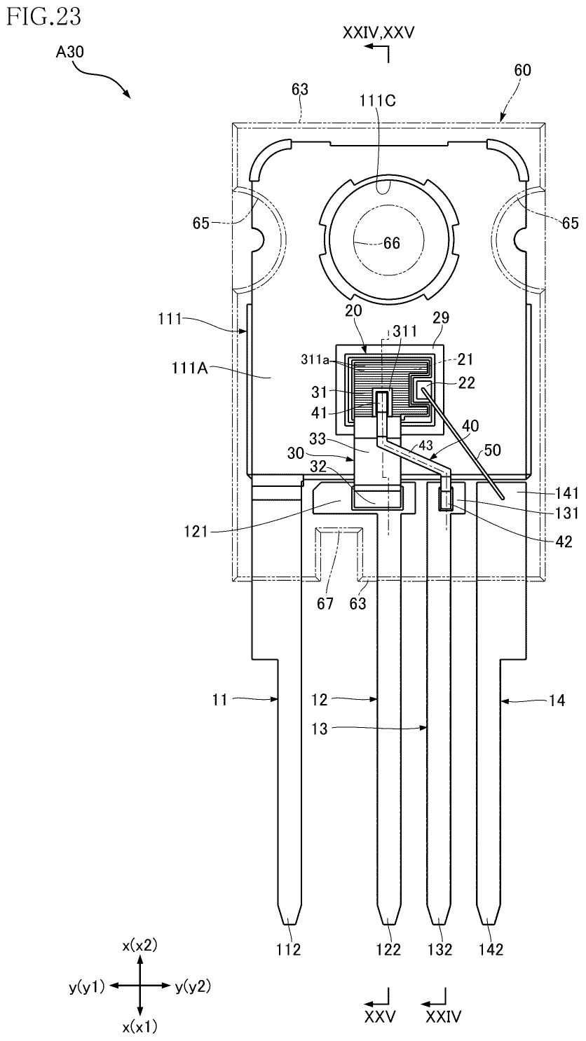

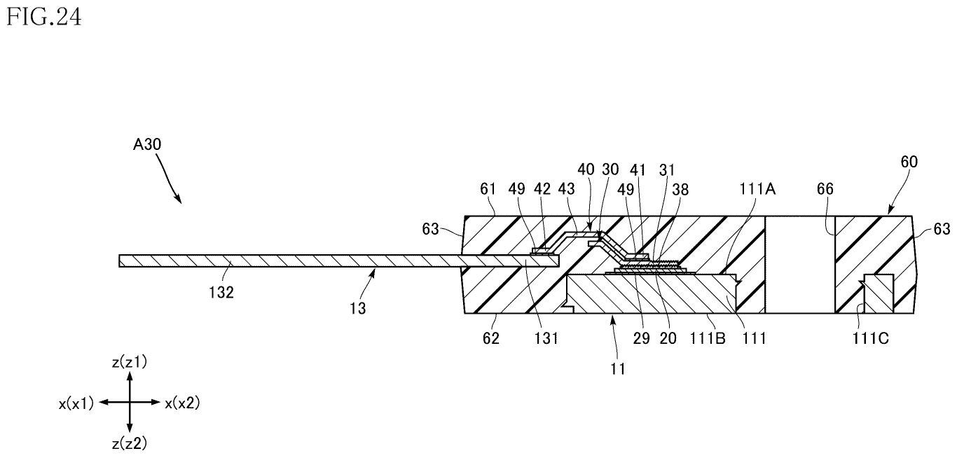

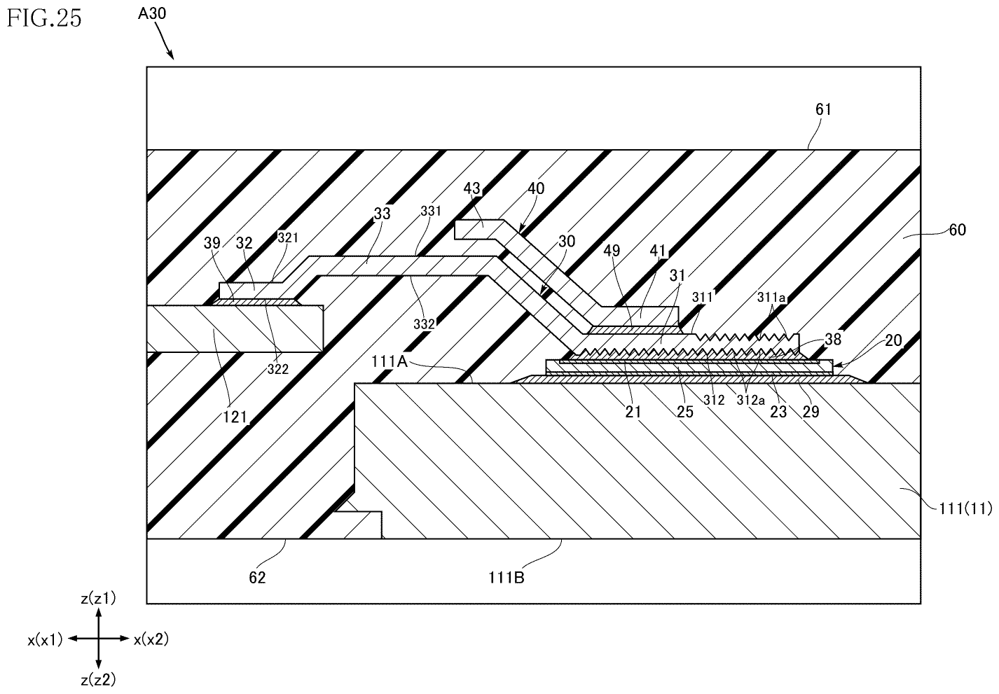

FIGS. 23 to 25 show a semiconductor device according to a third embodiment of the present disclosure. FIG. 23 is a plan view of a portion of a semiconductor device A30 according to the present embodiment. FIG. 24 is a sectional view taken along line XXIV-XXIV in FIG. 23. FIG. 25 is a sectional view taken along line XXV-XXV in FIG. 23. In FIG. 23, the outline of the sealing resin 60 is indicated by imaginary lines (dash-double-dot line). The semiconductor device A30 of the present embodiment differs from the semiconductor device A10 described above in the configuration of the first conductive member 30 and the arrangement of the second conductive member 40.

In the present embodiment, the second conductive member 40 is electrically bonded to the first portion 31 of the first conductive member 30 and the pad portion 131 of the third lead 13. The second conductive member 40 is made from a metal plate, for example. The constituent material of the second conductive member 40 includes copper (Cu), for example. The second conductive member 40 is a metal plate with appropriate bends. The second conductive member 40 includes a third portion 41, a fourth portion 42, and a second intermediate portion 43.

The third portion 41 is bonded to the first portion 31 of the first conductive member 30 via a bonding layer 49. The bonding layer 49 is made of a conductive material, such as solder or Ag (silver) paste. Thus, the third portion 41 is electrically connected to the first electrode 21 of the semiconductor element 20 via the first conductive member 30 (the first portion 31). In the illustrated example, the third portion 41 is positioned at the end of the second conductive member 40 on the x2 side in the first direction x.

The fourth portion 42 is bonded to the pad portion 131 of the third lead 13 via a bonding layer 49 and electrically connects the second conductive member 40 to the third lead 13. The bonding layer 49 is made of a conductive material, such as solder or Ag (silver) paste. In the illustrated example, the fourth portion 42 is positioned at the end of the second conductive member 40 on the x1 side in the first direction x.

As viewed in the thickness direction z, the second intermediate portion 43 is positioned between the third portion 41 and the fourth portion 42. The second intermediate portion 43 connects the third portion 41 and the fourth portion 42. As viewed in the second direction y, the second intermediate portion 43 is bent at the sections where it connects to the third portion 41 and the fourth portion 42. The section of the second intermediate portion 43, excluding the bent sections, lies parallel to the xy plane and is positioned further on the z1 side than the third portion 41 and the fourth portion 42. The parallel section of the second intermediate portion 43 extends in a direction intersecting both the first direction x and the second direction y, such that it is positioned closer to the y2 side in the second direction y as it approaches the x1 side in the first direction x.

The first surface 311 of the first conductive member 30 (the first portion 31) has a region in which no first recesses 311a are formed, along the edge on the x1 side in the first direction x and at the center in the second direction y. The third portion 41 (the second conductive member 40) is bonded to this region of the first surface 311 in which no first recesses 311a are formed. As viewed in the thickness direction z, the first recesses 311a are formed around the region of the first portion 31 where the second conductive member 40 is bonded.

In the present embodiment, the first portion 31 has a U-shape as viewed in the thickness direction z, with its legs extending along opposite sides of the second electrode 22 in the first direction x. Hence, the first portion 31 overlaps with most of the first electrode 21 as viewed in the thickness direction z. As viewed in the thickness direction z, the first recesses 311a are also formed on the legs of the first portion 31, which extend along opposite sides of the second electrode 22 in the first direction x.

The semiconductor device A30 is configured such that the first surface 311 of the first portion 31 has an uneven surface profile defined by the first recesses 311a. The first surface 311 is in contact with the scaling resin 60, thereby producing an anchoring effect that improves the bond between the first portion 31 (the first conductive member 30) and the scaling resin 60. In addition, the second surface 312 of the first portion 31 also has an uneven surface profile defined by the second recesses 312a. The second surface 312 is in contact with the first bonding layer 38, thereby producing an anchoring effect that improves the bond between the first portion 31 (the first conductive member 30) and the first bonding layer 38. This improves the reliability of the semiconductor device A30. Additionally, the semiconductor device A30 achieves the same operation and effects as the semiconductor device A10 described above.

Furthermore, the semiconductor device A30 is configured such that the second conductive member 40 is electrically bonded to the first portion 31 (the first conductive member 30) and the third lead 13. The second conductive member 40 is electrically connected to the first electrode 21 via the first conductive member 30. In the present embodiment, no space needs to be provided for a bonding tool to bond a wire to the first electrode 21. This allows the first portion 31 to have a larger area as viewed in the thickness direction z, and also allows the first recesses 311a and the second recesses 312a to be formed over a larger areas. With this configuration, the anchoring effect produced by the first recesses 311a and the second recesses 312a is further enhanced, improving the adhesion between the first portion 31 (the first conductive member 30) and the scaling resin 60, as well as the bond between the first portion 31 (the first conductive member 30) and the first bonding layer 38.

The semiconductor devices according to the present disclosure are not limited to the embodiments described above. Various modifications in design may be made freely in the specific structure of each part of the semiconductor device according to the present disclosure.

While the foregoing embodiments are described in the context of a discrete package including a lead as the first conductive support member (the first lead 11), and one semiconductor element 20 mounted on the base portion 111 of the first lead 11, the present disclosure is not limited to this configuration. For example, the semiconductor device may include a plurality of power semiconductor chips mounted on a copper plate or a DBC (direct bonded copper) substrate. In this example, each semiconductor chip corresponds to the semiconductor element of the present disclosure, and a metal layer of the copper plate or the DBC substrate corresponds to the first conductive support member of the present disclosure.

The present disclosure includes embodiments described in the following clauses.

### Clause 1.

A semiconductor device comprising:
a first conductive support member that includes a base portion;
a semiconductor element that is disposed on a portion of the base portion on a first side in a thickness direction and includes a first electrode on the first side in the thickness direction;
a second conductive support member that is spaced apart from the base portion in a first direction perpendicular to the thickness direction;
a first conductive member that is electrically bonded to the first electrode and the second conductive support member; and
a sealing resin that covers the semiconductor element, the first conductive member, a portion of the first conductive support member, and a portion of the second conductive support member,
wherein the first conductive member includes a first portion that is bonded to the first electrode via a conductive first bonding layer,
the first portion includes a first surface and a second surface respectively facing the first side and a second side in the thickness direction, and
the first portion includes a plurality of first recesses that are recessed from the first surface and a plurality of second recesses that are recessed from the second surface.

### Clause 2.

The semiconductor device according to Clause 1, wherein the plurality of first recesses and the plurality of second recesses are arranged along a direction perpendicular to the thickness direction and each comprise a linearly extending groove.

### Clause 3.

The semiconductor device according to Clause 1 or 2, wherein the first conductive member includes a second portion that is bonded to the second conductive support member via a conductive second bonding layer, the second portion includes a third surface and a fourth surface respectively facing the first side and the second side in the thickness direction, and the second portion includes a plurality of third recesses that are recessed from the third surface and a plurality of fourth recesses that are recessed from the fourth surface.

### Clause 4.

The semiconductor device according to Clause 3, wherein the plurality of third recesses and the plurality of fourth recesses are arranged along a direction perpendicular to the thickness direction and each comprise a linearly extending groove.

### Clause 5.

The semiconductor device according to Clause 3 or 4, wherein the first conductive member includes a first intermediate portion positioned between the first portion and the second portion as viewed in the thickness direction and connected to the first portion and the second portion,
the first intermediate portion includes a fifth surface and a sixth surface respectively positioned on the first side and the second side in the thickness direction, and
the first intermediate portion includes a plurality of fifth recesses that are recessed from the fifth surface and a plurality of sixth recesses that are recessed from the sixth surface.

### Clause 6.

The semiconductor device according to any one of Clauses 1 to 5, wherein the first conductive member includes a side surface facing in a direction perpendicular to the thickness direction, and
the first conductive member includes a plurality of seventh recesses that are recessed from the side surface.

### Clause 7.

The semiconductor device according to any one of Clauses 1 to 6, wherein the first conductive member extends longitudinally in the first direction.

### Clause 8.

The semiconductor device according to any one of Clauses 1 to 7, wherein the first conductive member is composed of a metal plate.

### Clause 9.

The semiconductor device according to Clause 8, wherein a constituent material of the first conductive member includes copper.

### Clause 10.

The semiconductor device according to any one of Clauses 1 to 9, further comprising:
a third conductive support member that is spaced apart from both the base portion and the second conductive support member; and
a second conductive member,
wherein the second conductive member is electrically connected to the first electrode and the third conductive support member.

### Clause 11.

The semiconductor device according to Clause 10, wherein the third conductive support member is spaced apart from the second conductive support member in a second direction perpendicular to the thickness direction and the first direction.

### Clause 12.

The semiconductor device according to Clause 10 or 11, wherein the second conductive member is electrically bonded to the first portion and the third conductive support member.

### Clause 13.

The semiconductor device according to Clause 12, wherein as viewed in the thickness direction, the plurality of first recesses surround a region where the first portion and the second conductive member are bonded.

### Clause 14.

The semiconductor device according to Clause 12 or 13, wherein the second conductive member is formed from a metal plate.

### Clause 15.

The semiconductor device according to Clause 12 or 13, wherein the second conductive member comprises a bonding wire.

### Clause 16.

The semiconductor device according to any one of Clauses 10 to 15, further comprising:
a fourth conductive support member that is spaced apart from the base portion in the first direction; and
a third conductive member,
wherein the semiconductor element includes a second electrode disposed on the first side in the thickness direction,
the fourth conductive support member is spaced apart from the third conductive support member in a second direction perpendicular to the thickness direction and the first direction, and
the third conductive member is electrically bonded to the second electrode and the fourth conductive support member.

### Clause 17.

The semiconductor device according to Clause 16, wherein the semiconductor element comprises a switching element that includes a drain electrode, a source electrode, and a gate electrode,
the first electrode comprises the source electrode,
the second electrode comprises the gate electrode, and
the drain electrode is disposed on the second side of the semiconductor element in the thickness direction and is electrically bonded to the base portion.

### Clause 18.

A vehicle comprising a power conversion device that includes the semiconductor device of Clause 17.

### REFERENCE NUMERALS

| | |
|---|---|
| A10, A11, A12, A13, A14, A20, A30: semiconductor device | |
| B1: vehicle | 11: first lead (first conductive support member) |
| 111: base portion | 111A: first obverse surface |
| 111B: first reverse surface | 111C: through-hole |
| 112: terminal portion | 12: second lead (second conducive support member) |
| 121: pad portion | 122: terminal portion |
| 13: third lead (third conducive support member) | 131: pad portion |
| 132: terminal portion | 14: fourth lead (fourth conducive support member) |
| 141: pad portion | 142: terminal portion |
| 20: semiconductor element | 21: first electrode (source electrode) |
| 22: second electrode (gate electrode) | 23: third electrode (drain electrode) |
| 25: semiconductor layer | 29: bonding layer |
| 30: first conductive member | 30A, 30B: side surface |
| 301: seventh recess | 31: first portion |
| 311: first surface | 311a: first recess |
| 312: second surface | 312a: second recess |
| 32: second portion | 321: third surface |
| 321a: third recess | 322: fourth surface |
| 322a: fourth recess | 33: first intermediate portion |
| 331: fifth surface | 331a: fifth recess |
| 332: sixth surface | 332a: sixth recess |
| 38: first bonding layer | 39: second bonding layer |
| 40: second conductive member | 41: third portion |
| 42: fourth portion | 43: second intermediate portion |
| 49: bonding layer | 50: third conductive member |
| 60: sealing resin | 61: resin obverse surface |
| 62: resin reverse surface | 63: first resin side surface |
| 64: first resin side surface | 65: opening |
| 66: mounting hole | 67: recessed portion |
| 80: charging station | 81: AC-DC conversion device (power conversion device) |
| 82: power receiving device | 83: storage battery |
| 84: drive system | |

1. A semiconductor device comprising:
a first conductive support member that includes a base portion;
a semiconductor element that is disposed on a portion of the base portion on a first side in a thickness direction and includes a first electrode disposed on the first side in the thickness direction;
a second conductive support member that is spaced apart from the base portion in a first direction perpendicular to the thickness direction;
a first conductive member that is electrically bonded to the first electrode and the second conductive support member; and
a sealing resin that covers the semiconductor element, the first conductive member, a portion of the first conductive support member, and a portion of the second conductive support member,
wherein the first conductive member includes a first portion that is bonded to the first electrode via a conductive first bonding layer,
the first portion includes a first surface and a second surface respectively facing the first side and a second side in the thickness direction, and
the first portion includes a plurality of first recesses that are recessed from the first surface and a plurality of second recesses that are recessed from the second surface.

2. The semiconductor device according to claim 1, wherein the plurality of first recesses and the plurality of second recesses are arranged along a direction perpendicular to the thickness direction and each comprise a linearly extending groove.

3. The semiconductor device according to claim 1, wherein the first conductive member includes a second portion that is bonded to the second conductive support member via a conductive second bonding layer,
the second portion includes a third surface and a fourth surface respectively facing the first side and the second side in the thickness direction, and
the second portion includes a plurality of third recesses that are recessed from the third surface and a plurality of fourth recesses that are recessed from the fourth surface.

4. The semiconductor device according to claim 3, wherein the plurality of third recesses and the plurality of fourth recesses are arranged along a direction perpendicular to the thickness direction and each comprise a linearly extending groove.

5. The semiconductor device according to claim 3, wherein the first conductive member includes a first intermediate portion positioned between the first portion and the second portion as viewed in the thickness direction and connected to the first portion and the second portion,
the first intermediate portion includes a fifth surface and a sixth surface respectively positioned on the first side and the second side in the thickness direction, and
the first intermediate portion includes a plurality of fifth recesses that are recessed from the fifth surface and a plurality of sixth recesses that are recessed from the sixth surface.

6. The semiconductor device according to claim 1, wherein the first conductive member includes a side surface facing in a direction perpendicular to the thickness direction, and
the first conductive member includes a plurality of seventh recesses that are recessed from the side surface.

7. The semiconductor device according to claim 1, wherein the first conductive member extends longitudinally in the first direction.

8. The semiconductor device according to claim 1, wherein the first conductive member is composed of a metal plate.

9. The semiconductor device according to claim 8, wherein a constituent material of the first conductive member includes copper.

10. The semiconductor device according to claim 1, further comprising:
a third conductive support member that is spaced apart from both the base portion and the second conductive support member; and
a second conductive member,
wherein the second conductive member is electrically connected to the first electrode and the third conductive support member.

11. The semiconductor device according to claim 10, wherein the third conductive support member is spaced apart from the second conductive support member in a second direction perpendicular to the thickness direction and the first direction.

12. The semiconductor device according to claim 10, wherein the second conductive member is electrically bonded to the first portion and the third conductive support member.

13. The semiconductor device according to claim 12, wherein as viewed in the thickness direction, the plurality of first recesses surround a region where the first portion and the second conductive member are bonded.

14. The semiconductor device according to claim 12, wherein the second conductive member is formed from a metal plate.

15. The semiconductor device according to claim 12, wherein the second conductive member comprises a bonding wire.

16. The semiconductor device according to claim 10, further comprising:
a fourth conducive support member that is spaced apart from the base portion in the first direction; and
a third conductive member,
wherein the semiconductor element includes a second electrode disposed on the first side in the thickness direction,
the fourth conductive support member is spaced apart from the third conductive support member in a second direction perpendicular to the thickness direction and the first direction, and
the third conductive member is electrically bonded to the second electrode and the fourth conductive support member.

17. The semiconductor device according to claim 16, wherein the semiconductor element comprises a switching element that includes a drain electrode, a source electrode, and a gate electrode,
the first electrode comprises the source electrode,
the second electrode comprises the gate electrode, and
the drain electrode is disposed on the second side of the semiconductor element in the thickness direction and is electrically bonded to the base portion.

18. A vehicle comprising a power conversion device that includes the semiconductor device of claim 17.
